(19) United States
(12) Patent Application Publication
(10) Pub. No.: US 2013/0220800 A1
(43) Pub. Date: Aug. 29, 2013

(54) METHOD FOR SPARK DEPOSITION USING CERAMIC TARGETS

(71) Applicant: Markus Lechthaler, Feldkirch (AT)

(72) Inventor: Markus Lechthaler, Feldkirch (AT)

(73) Assignee: OERLIKON TRADING AG, TRUBBACH, Trubbach (CH)

(21) Appl. No.: 13/695,839

(22) PCT Filed: Apr. 13, 2011
(86) PCT No.: PCT/EP2011/001856

§ 371 Date: Feb. 4, 2013

(30) Foreign Application Priority Data
May 4, 2010 (US) 61330935

(51) Int. Cl. C23C 14/32

(52) U.S. Cl. CPC C23C 14/325
USPC 204/192.38; 204/298.41

(57) ABSTRACT

The present invention relates to an arc deposition source, comprising an electrically conductive ceramic target plate (1), on the back of which a cooling plate (10) is provided, wherein a shield (3) is provided in the central area on the surface to be coated so that the cathode spot of the arc does not reach the central area (6) of the surface during operation of the deposition source.

### TECHNICAL FIELD THE INVENTION TO WHICH THE INVENTION PERTAINS

The present invention relates to a method for coating work pieces by means of cathodic spark vaporization and electrically conductive ceramic targets. The invention relates in particular to a source for a coating facility for executing the aforementioned method. The invention pertains in particular to a coating facility for executing the aforementioned method.

### STATE OF THE ART TO DATE

It is known to coat work pieces by generating in a vacuum chamber a plasma in the form of a high-current, low-voltage arc discharge onto a material source, hereinafter called target. The material to be vaporized in this process is put as cathode at the negative pole of a voltage supply source. The arc is ignited by means of an ignition device. The arc melts the cathode at one or several cathode spots in which the current transfer is concentrated. In doing so, electrons are essentially extracted out of the cathode. In order to maintain the arc, it is thus necessary to continuously provide an electron supply at the corresponding cathode surface. The electric arc, also called synonymously arc, moves more or less stochastically on the cathode surface. This results in an extremely fast heating of small target surface areas, whereby material is locally vaporized. In the case of metallic target materials, this is not a problem, since they have essentially both the thermal shock resistance as well as the heat conductivity to withstand such a punctual heat shock induced by the arc without any damage.

In the case of spark vaporization of metallic targets, the droplet issue however plays an important role: the fast localized heating up of the metallic target material causes macroscopic splatters that originate from the molten target material to be flung From the target and to be deposited as droplet onto the surfaces to be coated. Such droplets can have an extremely negative influence on the layer properties, such as for example resistance to wear and tear or surface roughness. Much effort is thus expended in order to essentially prevent such droplets. One possibility consists in filtering out the droplets before they can deposit onto the substrate. Such a measure is however laborious and usually has a mostly negative influence on the coating rate. Since the droplet formation increases the slower the arc moves on the metallic target surface, there is also a possibility of reducing the droplet problem by forcing the arc into a fast movement on the target surface, for example by means of horizontal magnetic field lines oriented radially. Published patent application WO200016373 discloses in this connection a configuration of a coating source wherein magnetic means are provided behind the metallic target that cause such a desired magnetic field distribution outside the central area of the target. Since vertical components of the magnetic field are predominant in the central area of the target that would virtually trap the arc, the arc is prevented from reaching this area by means of a cover. Boron nitride and/or titanium nitride are for example indicated as cover. These materials have, as described therein, a lower secondary electron emission rate and a lower surface energy than the metallic target material.

It must be noted here that in the context of ceramic targets, the droplet issue essentially does not arise. In the case of ceramic targets, the fusion of the target material is considerably more complex because of the high melting point than in the case of metallic compounds of this type. Vaporization is probably more a sublimation process. Most of the particles knocked out macroscopically out of the ceramic target surface by the arc are so large, that because of gravity they do not and on the work pieces to be coated but rather settle at the bottom of the coating chamber. Though the layer formed on the work pieces comprises measurable so-called droplets, these are however in such small density that no further measures against them are necessary.

In contrast thereto, a major problem must be seen in that ceramic materials mostly have a very low thermal shock resistance. If the material is not resistant to heat shocks, cracks will form that the cathode spot of the arc can only overcome with difficulty. There is as yet no full explanation of why such a trapping would result at cracks. A possible explanation would be conceivable with the aid of the so-called field emission effect, wherein electrons exit more easily at Ups and edges. The longer retention time means an additional localized heating of the material, which in the case of ceramic materials leads to a localized decrease of the threshold for electron emission. This however means in turn that the arc, which always seeks those areas of the surface from which it can most easily emit electrons, lingers even longer at the crack. It is thus a self-reinforcing destructive effect. Therefore, ceramic targets are at present essentially not used industrially for spark vaporization. One exception to this is tungsten carbide, whose thermal shock resistance is lower as compared in particular to other ceramic materials, such as for example titanium nitride (TiN), titanium boride (TiB₂), ZrB₂, NbB₂, tungsten boride (WB) or tungsten nitride (W₂N), At present, only spark vaporization on the basis of tungsten carbide targets (NC targets) is therefore widespread.

There is however a need in the market to be able to vaporize economically by means of electric arcs also such layer materials of ceramic targets for which this has not been possible so far at least on an industrial scale. In particular, TiN, TiB₂, WB and/or also W₂N targets should be capable of being used for arc vaporization without the target breaking prematurely.

In the case of TiB₂ targets, the article “Ceramic cathodes for arc-physical vapor deposition: development and application” by O. Knotek, F. Löffler, in: Surface and Coating Technology 49 (1991), pages 263 to 267, mentions problems that sees an increase in the concentration of the cathode spot in a localized area, which results in overheating and even to breaking of the plate.

The task of the invention is thus to be able to arc-vaporize also such layer materials of ceramic targets for which this has not been possible so far at least on an industrial scale. In particular, TiN, TiB₂, WB and/or also W₂N targets should be capable of being used for arc vaporization without the target breaking prematurely.

The inventors thus asked themselves the question of how the heat shock transferred by the arc onto the target could be absorbed efficiently. It is known from sputtering technology, which is a PVD coating process that constitutes an alternative to spark evaporation, that sputter target material can be bonded with so-called cooling plates in order to enable an efficient heat dissipation. Such cooling plates have high heat conductivity and are fastened across as a large an area as possible and with good thermal bridges to the sputter target material. These cooling plates preferably have a similar coefficient of expansion as the target material used for the sputtering. Due to the high target performances during sputtering, caused by the comparatively high discharge voltage, a high thermal input is generated on the sputter target, though it is uniformly distributed over the entire target.

The thermal stresses arising during spark vaporization that could result in heat shocks are however localized and are characterized by high temperature gradients, which cause a mechanical overuse of the ceramic target. In contrast thereto, the thermal shock resistance is irrelevant in the case of sputtering, because of the uniform temperature distribution in the target.

The simple use of a cooling plate with the ceramic target used for arc vaporization therefore does not yield a satisfying result. The risk of the target breaking is still prominent. Additionally, the localized temperature increase often results in the bonding connection suffering localized damage precisely there and thus in no good thermal contact existing any more where it would in fact be most necessary.

However, the inventors did discover that some measures that cause a reduction of the droplet issue in connection with the spark vaporization of metallic targets, in connection with ceramic targets surprisingly result in spark vaporization being usable reliably and without damage to the ceramic target provided with a cooling plate. According to the invention, the spark vaporization is thus performed in such a manner that a ceramic target, on the back of which a cooling plate is bonded, is arc vaporized, characterized in that the electric arc is constrained to a fast movement on the target surface,

An inventive electric arc source for coating facilities for arc vaporization thus comprises at least one ceramic target, on the back of which a cooling plate is provided with a good thermal contact, preferably bonded, characterized in that means are provided in the facility with which the cathode spot of the electric arc is constrained to a movement that reduces the localized warming and thus the formation of microfissures and, even in the event of small microfissures forming, prevents the increased probability of the cathode spot lingering in this place.

The invention will hereinafter be explained in more detail on the basis of figures, which show:

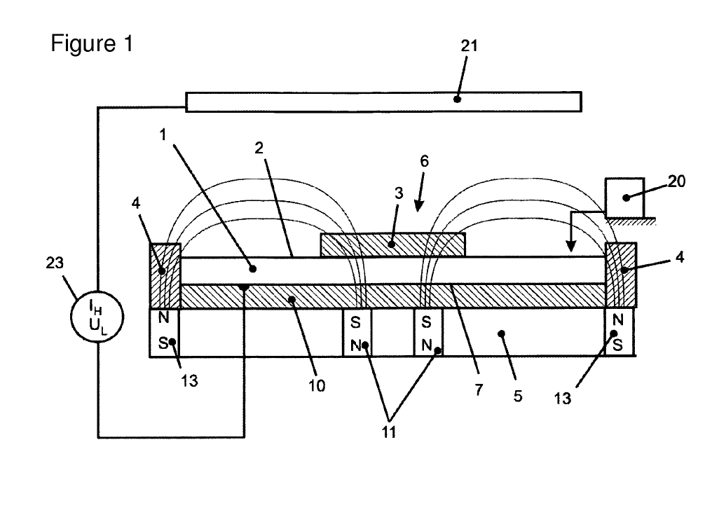

FIG. 1 an inventive source with an inventive target pate in a schematic side view;

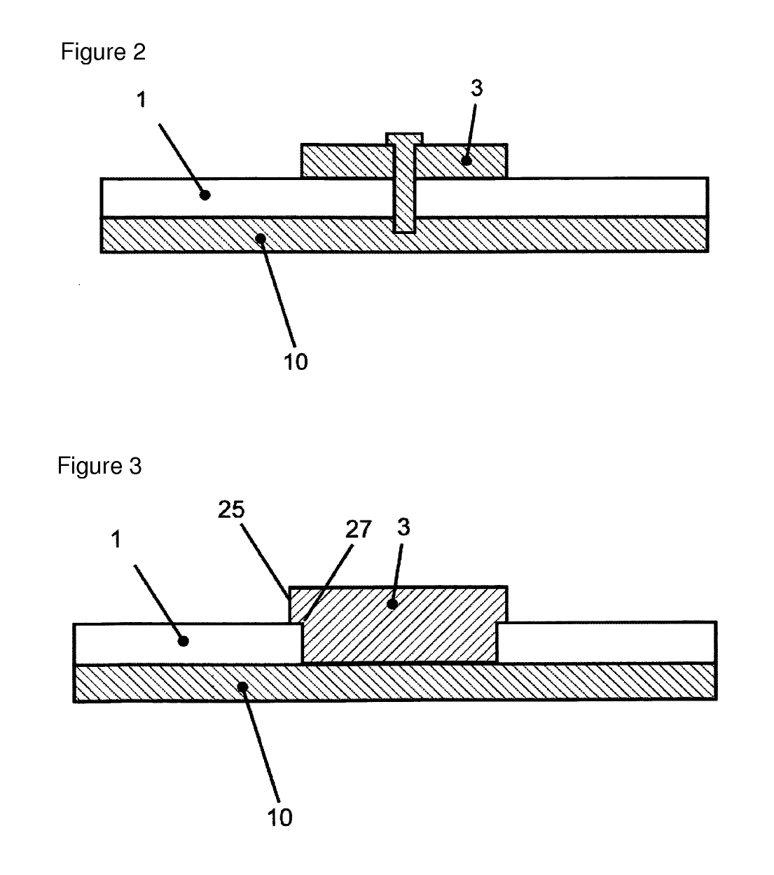

FIG. 2 an embodiment of an inventive component of the electric arc source;

FIG. 3 a further embodiment of an inventive component of the electric arc source.

FIG. 1 shows an inventive arc deposition source as used in an arc vaporization chamber for coating substrates. R usually comprises an ignition device 20—represented purely schematically—for igniting the electric arc. Furthermore, an electric high-current I_{H}, low-voltage U_{L}. DC voltage supply source 23 is connected between the target plate 1 and an anode 21, again represented purely schematically.

The inventive electric arc source comprises the electrically conductive ceramic target plate 1 with the surface 2 to be vaporized. On the reverse surface 7 of the target plate 1, i.e. on the surface turned away from the surface 2 to be vaporized, a cooling pate 10 is provided that is operatively connected thermally across a large area. The cooling plate 10 consists of a material with high heat conductivity. Thanks to the large area thermal contact, the cooling plate is capable of distributing the localized energy input caused by the cathode spot on the target surface 2 quickly and efficiently over the entire target cross section. This precautionary measure will thus already lessen somewhat the risk of the target plate 1 becoming destroyed because of heat shocks. If the cooling plate is moreover electrically conductive, the electric contact of the target plate 1 to the voltage supply source 23 can be achieved through the cooling plate 10. Molybdenum, for example, can be used as material for the cooling plate, but R is also possible to use other materials as known from sputtering technology.

The thermal operative connection is preferably achieved by the cooling plate being bonded to the target plate. However, it has been shown that despite the cooling plate, localized heating occurs that causes the electrons locally to exit more easily. Without further measures, the spot will thus linger in this place, which results in the heat shock taking on significant orders of magnitude that even the cooling plate can no longer absorb.

The inventive arc deposition source thus furthermore comprises means that constrain the cathode spot reap. if necessary the cathode spots of the electric arc to a movement over the target and, where appropriate, away from the microfissures. In the embodiment illustrated in FIG. 1, these means comprise inner permanent magnets 11 arranged behind the cooling plate and an outer ring magnet 13 that is oriented with opposing polarity to the inner permanent magnets 11. Because of the inner permanent magnets 11 and the outer ring magnets 13, magnetic field lines run over the surface 2 to be vaporized from north to south resp. from south to north. Horizontal components of the magnetic field formed over the surface 2 lead to a constrained movement of the cathode spot of the electric arc over the surface 2. In the present case, in contrast thereto, vertical components of the magnetic field formed over the surface 2 will result in the cathode spot or spots of the electric arc essentially lingering on the corresponding place of the surface or in its/their movement being at least slowed down.

In the embodiment of the present invention discussed here, measures are thus taken in order to keep the cathode spot away from areas of the surface 2 at which vertical components of the magnetic field predominate. A cover 3 is thus provided in a central area on the surface 2 of the electrically conductive ceramic target plate 1, wherein the cover 3 is made in such a manner that in this area no electron supply is provided any more that could feed the electric arc at the cathode spot. In the present example, at least the surface of the cover 3 consists of non-conductive material, such as for example Al₂O₃ or boron nitride, It would however also be conceivable to make the cover 3 of conductive material but to insulate it from the voltage supply source 23 or at least put it in less good electric contact with the voltage supply source 23. With such an arrangement, the electron supply is prevented or at least strongly inhibited.

The cathode spot of the electric arc will preferably stray to where sufficient electron supply is provided and will thus avoid the central area 6 in which vertical components of the magnetic field predominate. Different inventive arrangements are conceivable and the one skilled in the art will chose appropriate executions that are best suited to his situation.

FIG. 2 shows schematically a target plate 1 with bonded cooling plate 10, The target plate has a central boring and the cooling plate 10 has an inner threading so that an inventive shield 3 can be screwed onto the combination of target plate 1 and cooling plate 10 by means of a screw 15, also shown,

FIG. 3 illustrates a further inventive embodiment of a target pate 1 with bonded cooling plate 10 and shield 3. In this embodiment, the shield 3 is embedded in a large-size hole in the target plate 1. There is preferably a small transition from the shield 3 over the target plate 1, as shown, in order to prevent the cathode spot From getting into the vicinity of an edge of the target plate 1 and being virtually trapped there,

What is claimed is:

1. Arc deposition source, comprising:
a cathode with an electrically conductive ceramic target plate (1),
an anode (21),
a voltage supply source (23), which is interconnected with the target plate (1) and the anode (21) in such a manner that the target plate (1) opposite the anode (21) can be put to negative potential,
an ignition device (20) for igniting the arc,
characterized in that
the target plate (1) is operatively connected thermally across a large area and preferably by means of a bonding connection with a cooling plate (10),
and means are provided for constraining the movement of the cathode spot.

2. Arc deposition source according to claim 1, characterized in that the movement-constraining means are arranged in such a manner that the cathode spot can be maintained in movement even when microfissures are present in the target plate.

3. Arc deposition source according to claim 1, characterized in that the means for constraining the movement of the cathode spot have essentially the same effect on the deposition surface, i.e. everywhere where the cathode spot may reach on the surface of the target plate.

4. Arc deposition source according to claim 3, characterized in that the means for constraining the movement of the cathode spot comprise magnetic means resulting in an essentially uniform movement of the cathode spot.

5. Arc deposition source according to claim 4, characterized in that the magnetic means are designed in such a way that they result in an essentially homogeneous magnetic field on the deposition surface, whose field lines are aligned essentially vertically to the deposition surface or alternatively are oriented on the entire deposition surface at an angle greater than 45° perpendicular to the deposition surface.

6. Arc deposition source according to claim 1, characterized in that the movement-constraining means comprise, on the side of the cooling plate, inner permanent magnets and one outer permanent magnet ring, oriented with opposing polarity to the inner permanent magnets, so that a magnetic field distribution is formed over the surface to be vaporized (2) of the target plate (1) and in that the movement-constraining means comprise a shield (3) in the central area (6) of the surface to be vaporized (2), wherein the surface of the shield (3) is at least essentially electrically insulated from the voltage supply source (23) and thus during operation of the deposition source no electron supply is available in this area.

7. Arc deposition source according to claim 5, characterized in that the shield (3) is made of electrically insulating material, preferably of aluminum oxide or boron nitride or has an aluminum oxide or boron nitride surface.

8. Coating facility for coating substrates with at least one arc deposition source according to claim 1.

9. Method for coating substrates, characterized in that a coating facility according to claim 8 is used for the coating.
